(19) United States
(12) Patent Application Publication
(10) Pub. No.: US 2014/0242504 A1
(43) Pub. Date: Aug. 28, 2014

(54) POSITIVE PHOTOSENSITIVE RESIN COMPOSITION AND METHOD FOR FORMING PATTERNS BY USING THE SAME

(71) Applicant: CHI MEI CORPORATION, Tainan City (TW)

(72) Inventors: Chi-Ming LIU, KAOHSIUNG CITY (TW); Chun-An SHIH, TAINAN CITY (TW)

(73) Assignee: CHI MEI CORPORATION, Tainan City (TW)

(21) Appl. No.: 14/184,674

(22) Filed: Feb. 19, 2014

(30) Foreign Application Priority Data
Feb. 22, 2013 (TW) 02106239

(51) Int. Cl. G03F 7/039; G03F 7/40

(52) U.S. Cl. CPC G03F 7/039; G03F 7/40
USPC 430/18; 430/286.1; 430/326

(57) ABSTRACT

The present invention relates to a positive photosensitive resin composition and a method for forming patterns by using the same. The positive photosensitive resin composition includes a novolac resin (A), an ortho-naphthoquinone diazide sulfonic acid ester (B), a hydroxycompound (C) and a solvent (D). The novolac resin (A) further includes a hydroxy-type novolac resin (A-1) and a xylenol-type novolac resin (A-2). The hydroxy-type novolac resin (A-1) is synthesized by condensing hydroxyl benzaldehyde compound with aromatic hydroxyl compound. The xylenol-type novolac resin (A-2) is synthesized by condensing aldehyde compound with xylenol compound. The postbaked positive photosensitive resin composition can be beneficially formed to patterns with high film thickness and well cross-sectional profile.

### RELATED APPLICATIONS

This application claims priority to Taiwan Application Serial Number 102106239, filed Feb. 22, 2013, which is herein incorporated by reference.

### BACKGROUND

1. Field of Invention

The present invention relates to a positive photosensitive resin composition and a method for forming patterns by using the same. More particularly, the present invention relates to a positive photosensitive resin composition for forming patterns which are postbaked to have high film thickness and excellent cross-sectional profile during the manufacturation of thin-film transistor (TFT) liquid crystal display (LCD) or touch panel.

### DESCRIPTION OF RELATED ART

Depending upon the microminiaturization of various electronic products in daily life, the demand for high resolution in various smart phones, slim TVs and microprocessors with high-performance is increased gradually, so that a more accurate representation of the photolithography process is required to form patterns with finer line width.

For the aforementioned purposes, a positive photosensitive resin composition disclosed in the Japanese Patent Laid-open publication No. 2003-98669 includes a novolac resin, a photoacid generator and an organic solvent. The novolak resin is obtained by reacting phenols including ≧50 wt. % m-cresol (except from m-cresol, such as trimethyl phenol, xylenol and ortho-cresol) with aldehydes in the presence of an acid catalyst, and a part or all of the hydroxyl groups of the novolak resin is protected by alkoxyalkyl groups, thereby elevating the sensibility and resolution of the positive photosensitive resin composition. Moreover, a positive photosensitive resin composition disclosed in the Japanese Patent Laid-open publication No. 2001-183838 includes a novolac resin, a photoacid generator and a cross-linking agent that is catalyzed by acids. The novolak resin is obtained by carrying out the polycondensation of an alkaline soluble resin with a cresol compound and/or a xylenol compound under existence of an acid catalyst, thereby increasing the sensibility and resolution of the positive photosensitive resin composition.

However, in the prior arts, after the photosensitive resin composition is postbaked, it is often found problems that the postbaked photosensitive resin composition is unlikely formed to patterns with high film thickness. Moreover, the formed patterns with bad cross-sectional profile cause the worse yield of the subsequent process. Therefore, it is important how to postbake the positive photosensitive resin composition for forming patterns with high film thickness and well cross-sectional profile.

Accordingly, it is desired to provide a positive photosensitive resin composition material for forming patterns that have high film thickness and well cross-sectional profile after being postbaked, so as to overcome the aforementioned problems of the prior art.

### SUMMARY

Therefore, an aspect of the present invention provides a positive photosensitive resin composition, which includes a novolac resin (A), an ortho-naphthoquinone diazide sulfonic acid ester (B), a hydroxycompound (C) and a solvent (D). The novolac resin (A) further includes hydroxy-type novolac resin (A-1) and xylenol-type novolac resin (A-2). The hydroxy-type novolac resin (A-1) is synthesized by condensing hydroxyl benzaldehyde compound with aromatic hydroxyl compound. The xylenol-type novolac resin (A-2) is synthesized by condensing aldehyde compound with xylenol compound.

Another aspect of the present invention provides a method for forming patterns which subjects the above-mentioned positive photosensitive resin composition into a coating step, a prebake step, an exposure step, a development step and a postbake step, so as to form patterns on a substrate. The patterns formed by the above-mentioned positive photosensitive resin have high film thickness and well cross-sectional profile after being postbaked.

Still another aspect of the present invention provides a thin-film transistor (TFT) array substrate, which includes the above-mentioned patterns.

Yet still another aspect of the present invention provides a liquid crystal display (LCD) device, which includes the above-mentioned TFT array substrate.

The positive photosensitive resin composition, the structures of the TFT array substrate and the LCD device and the method of forming patters of the present invention are respectively described below.

### Positive Photosensitive Resin Composition

The positive photosensitive resin composition of the present invention includes a novolac resin (A), an ortho-naphthoquinone diazide sulfonic acid ester (B), a hydroxycompound (C) and a solvent (D), which are respectively described below.

### Novolac Resin (A)

The novolac resin (A) of the present positive photosensitive resin composition includes hydroxy-type novolac resin (A-1), and optionally further include xylenol-type novolac resin (A-2).

The above-mentioned hydroxy-type novolac resin (A-1) is synthesized by condensing hydroxyl benzaldehyde compound with aromatic hydroxyl compound in the presence of acid catalyst.

The specific examples of the above-mentioned hydroxyl benzaldehyde compound include: hydroxyl benzaldehyde compound such as o-hydroxyl benzaldehyde, m-hydroxyl benzaldehyde, p-hydroxyl benzaldehyde and the like; dihydroxyl benzaldehyde compound such as 2,3-dihydroxyl benzaldehyde, 2,4-dihydroxyl benzaldehyde, 2,5-dihydroxyl benzaldehyde, 3,4-dihydroxyl benzaldehyde, 3,5-dihydroxyl benzaldehyde and the like; trihydroxyl benzaldehyde compound such as 2,3,4-trihydroxyl benzaldehyde, 2,4,5-trihydroxyl benzaldehyde, 2,4,6-trihydroxyl benzaldehyde, 3,4,5-trihydroxyl benzaldehyde and the like; and hydroxyl alkyl benzaldehyde compound such as o-hydroxymethyl benzaldehyde, m-hydroxymethyl benzaldehyde, p-hydroxymethyl benzaldehyde and the like. The hydroxyl benzaldehyde compound can be used alone or in combinations of two or more. Among those hydroxyl benzaldehyde compounds, o-hydroxyl benzaldehyde, m-hydroxyl benzaldehyde, p-hydroxyl benzaldehyde, 2,3-dihydroxyl benzaldehyde, 2,4-dihydroxyl benzaldehyde, 3,4-dihydroxyl benzaldehyde, 2,3,4-trihydroxyl benzaldehyde and o-hydroxylmethyl benzaldehyde are preferred.

Moreover, the specific examples of the aromatic hydroxyl compound that can be condensed with the above-mentioned hydroxyl benzaldehyde compound include: phenol; cresols such as m-cresol, p-cresol and o-cresol; xylenols such as 2,3-xylenol, 2,5-xylenol, 3,5-xylenol, 3,4-xylenol and the like; alkyl phenols such as m-ethyl phenol, p-ethyl phenol, o-ethyl phenol, 2,3,5-trimethylphenol, 2,3,5-triethylphenol, 4-tert-butyl phenol, 3-tert-butyl phenol, 2-tert-butyl phenol, 2-tert-butyl-4-methylphenol, 2-tert-butyl-5-methylphenol, 6-tert-butyl-3-methylphenol and the like; alkoxy phenols such as p-methoxy phenol, m-methoxy phenol, p-ethyoxyl phenol, m-ethyoxyl phenol, p-propoxy phenol, m-propoxy phenol and the like; isopropenyl phenols such as o-isopropenyl phenol, p-isopropenyl phenol, 2-methyl-4-isopropenyl phenol, 2-ethyl-4-isopropenyl phenol and the like; aryl phenols such as phenyl phenol; polyhydroxyphenols such as 4,4′-dihydroxybiphenyl, bisphenol A, resorcinol, hydroquinone, 1,2,3-pyrogallol and the like. The above-mentioned aromatic hydroxyl compound can be used alone or in combinations of two or more. Among those aromatic hydroxyl compounds, o-cresol, m-cresol, p-cresol, 2,5-xylenol, 3,5-xylenol, 2,3,5-trimethylphenol and the like are preferred.

Specific examples of the above-mentioned acid catalyst include hydrochloric acid, sulfuric acid, formic acid, acetic acid, oxalic acid and p-toluenesulfonic acid and the like.

As for the xylenol-type novolac resin (A-2), it is generally synthesized by condensing an aldehyde compound with a xylenol compound with in the presence of the above-mentioned acid catalyst.

Specific examples of the above-mentioned aldehyde compound include: formaldehyde, paraformaldehyde, trioxane, acetaldehyde, propionaldehyde, butyraldehyde, trimethylacetaldehyde, acrolein, crotonaldehyde, cyclo hexanealdehyde, furfural, furylacrolein, benzaldehyde, terephthal aldehyde, phenylacetaldehyde, α-phenylpropyl aldehyde, β-phenylpropyl aldehyde, o-methyl benzaldehyde, m-methyl benzaldehyde, p-methyl benzaldehyde, o-chlorobenzaldehyde, m-chlorobenzaldehyde, p-chlorobenzaldehyde and cinnamaldehyde and the like. The above-mentioned aldehyde compound can be used alone or in combinations of two or more. Among those aldehyde compounds, methanal and benzaldehyde are preferred.

Specific examples of the above-mentioned xylenol compound include: 2,3-xylenol, 2,5-xylenol, 3,5-xylenol and 3,4-xylenol are preferred.

Without affecting the whole properties, the positive photosensitive resin composition of the present invention may optionally include an other novolac resin (A-3), which is formed by condensing an aldehyde compound with an aromatic hydroxyl compound with in the presence of the above-mentioned acid catalyst. The aldehyde compound and the aromatic hydroxyl compound, both of which are listed as aforementioned without being recited repetitively, have different structures from the hydroxy-type novolac resin (A-1) and the xylenol-type novolac resin (A-2).

The hydroxy-type novolac resin (A-1), the xylenol-type novolac resin (A-2) and the other novolac resin (A-3) can be used one kind of novolac resin or in combinations of two or more different kinds of novolac resins. Based on an amount of the novolac resin (A) as 100 parts by weight, the amount of the hydroxy-type novolac resin (A-1) is generally 50 to 95 parts by weight, the amount of the xylenol-type novolac resin (A-2) is generally 5 to 50 parts by weight, and the amount of the other novolac resin (A-3) is generally 0 to 45 parts by weight. The hydroxy-type novolac resin (A-1) has better developability, and the xylenol-type novolac resin (A-2) has better film-remaining ratio. When the hydroxy-type novolac resin (A-1) or the xylenol-type novolac resin (A-2) is not used in the positive photosensitive resin composition, the resulted positive photosensitive resin composition has problems such as bad cross-sectional profile and insufficient film thickness after being postbaked. However, when the positive photosensitive resin composition has the aforementioned amounts of the hydroxy-type novolac resin (A-1) and the xylenol-type novolac resin (A-2), the resulted positive photosensitive resin composition has the advantage of better cross-sectional profile after being postbaked, and it prevents the resulted patterns from the defect of insufficient film thickness due to the flow of the heated patterns during the postbake step.

Moreover, based on the total amount of the hydroxy-type novolac resin (A-1) and the xylenol-type novolac resin (A-2) as 100 percentage by weight, the amount of the hydroxy-type novolac resin (A-1) is generally 50 to 95 percentage by weight, and the amount of the xylenol-type novolac resin (A-2) is generally 5 to 50 percentage by weight. When the positive photosensitive resin composition has 50 to 95 parts by weight of the hydroxy-type novolac resin (A-1) and 5 to 50 parts by weight of the xylenol-type novolac resin (A-2), the resulted positive photosensitive resin composition has better cross-sectional profile after being postbaked.

### Ortho-Naphthoquinone Diazide Sulfonic Acid Ester (B)

The ortho-naphthoquinone diazide sulfonic acid ester (B) of the present positive photosensitive resin composition can be selected from the conventionally common ones without any specific limitation. In preferred examples of the present invention, the above-mentioned ortho-naphthoquinone diazide sulfonic acid ester (B) can include but not limited to: esters of ortho-naphthoquinone diazide sulfonic acid and a hydroxyl compound such as ortho-naphthoquinone diazide-4-sulfonic acid, ortho-naphthoquinone diazide-5-sulfonic acid and ortho-naphthoquinone diazide-6-sulfonic acid. However, the above-mentioned ester of the ortho-naphthoquinone diazide sulfonic acid and a polyhydroxyl compound is preferred.

The above-mentioned ortho-naphthoquinone diazide sulfonic acid ester (B) can be esterified completely or partially. The kinds of the above-mentioned hydroxyl compound can be exemplified as: (1) hydroxybenzophenones, and/or (2) hydroxyaryl compounds of Formula (I), and/or (3) (hydroxyphenyl) hydrocarbon compounds of Formula (II), which are respectively described below.

(1) Specific examples of the hydroxybenzophenone include: 2,3,4-trihydroxybenzophenone, 2,4,4′-trihydroxybenzophenone, 2,4,6-trihydroxybenzophenone, 2,3,4,4′-tetrahydroxybenzophenone, 2,2′,4,4′-tetrahydroxybenzophenone, 2,3′,4,4′,6-pentahydroxybenzophenone, 2,2′,3,4,4′-pentahydroxybenzophenone, 2,2′,3,4,5′-pentahydroxybenzophenone, 2,3′,4,5,5′-pentahydroxybenzophenone or 2,3,3′,4,4′,5′-hexahydroxybenzophenone.

(2) Specific examples of the hydroxyaryl compound have a structure as shown in Formula (I):

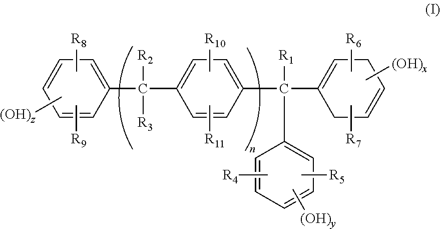

In Formula (I), R₁ to R₅ each independently represents a hydrogen atom or a lower alkyl group; R₄-R₉ each independently represents a hydrogen atom, a halogen atom, a lower alkyl group, a lower alkoxy group, a lower alkenyl group and a cycloalkyl group; R₁₀ and R₁₁ each independently represents a hydrogen atom, a halogen atom and a lower alkyl group; x and y each independently represents a integer of 1 to 3; z represents a integer of 0 to 3; and n is 0 or 1.

In preferred examples of the present invention, the hydroxyaryl compound with a structure shown in Formula (I) is tris(4-hydroxyphenyl)methane, bis(4-hydroxy-3,5-dimethylphenyl)-4-hydroxyphenyl methane, bis(4-hydroxy-3,5-dimethyl phenyl)-3-hydroxyphenyl methane, bis(4-hydroxy-3,5-dimethyl phenyl)phenyl methane, bis(4-hydroxyphenyl)phenyl ethane, bis(4-hydroxy-3-t-butylphenyl)phenyl ethane, bis(4-hydroxy-3,5-dimethylphenyl)-2-hydroxyphenyl methane, bis(4-hydroxy-2,5-dimethylphenyl)-4-hydroxyphenyl methane, bis(4-hydroxy-2,5-dimethylphenyl)-3-hydroxyphenyl methane, bis(4-hydroxy-2,5-dimethylphenyl)-2-hydroxyphenyl methane, bis(4-hydroxy-3,5-dimethylphenyl)-3,4-dihydroxyphenyl methane, bis(4-hydroxy-2,5-dimethylphenyl)-3,4-dihydroxyphenyl methane, bis(4-hydroxy-3,5-dimethylphenyl)-2,4-dihydroxyphenyl methane, bis(4-hydroxy-2,5-dimethylphenyl)-2,4-dihydroxyphenyl methane, bis(4-hydroxyphenyl)-3-methoxyl-4-hydroxyphenyl methane, bis(3-cyclohexyl-4-hydroxyphenyl)-3-hydroxyphenyl methane, bis(3-cyclohexyl-4-hydroxyphenyl)-2-hydroxyphenyl methane, bis(3-cyclohexyl-4-hydroxyphenyl)-4-hydroxyphenyl methane, bis(3-cyclohexyl-4-hydroxy-6-methylphenyl)-2-hydroxyphenyl methane, bis(3-cyclohexyl-4-hydroxy-6-methylphenyl)-3-hydroxyphenyl methane, bis(3-cyclohexyl-4-hydroxy-6-methylphenyl)-4-hydroxyphenyl methane, bis(3-cyclohexyl-4-hydroxy-6-methylphenyl)-3,4-dihydroxyphenyl methane, bis(3-cyclohexyl-6-hydroxyphenyl)-3-hydroxyphenyl methane, bis(3-cyclohexyl-6-hydroxyphenyl)-4-hydroxyphenyl methane, bis(3-cyclohexyl-6-hydroxyphenyl)-2-hydroxyphenyl methane, bis(3-cyclohexyl-6-hydroxy-4-methylphenyl)-2-hydroxyphenyl methane, bis(3-cyclohexyl-6-hydroxy-4-methylphenyl)-4-hydroxyphenyl methane, bis(3-cyclohexyl-6-hydroxy-4-methylphenyl)-3,4-dihydroxyphenyl methane, 1-[1-(4-hydroxyphenyl)isopropyl]-4-[1,1-bis(4-hydroxyphenyl)ethyl]benzene or 1-[1-(3-methyl-4-hydroxyphenyl)isopropyl]-4-[1,1-bis(3-methyl-4-hydroxyphenyl)ethyl]benzene.

(3) Specific examples of the (hydroxyphenyl) hydrocarbon compound have a structure as shown in Formula (II) as follows:

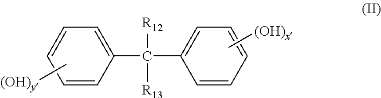

In Formula (II), R₁₂ and R₁₃ each independently represents a hydrogen atom or a lower alkyl; group and x′ and y′ each independently represents an integer of 1 to 3.

In preferred examples of the present invention, the (hydroxyphenyl) hydrocarbon compound with a structure as shown in Formula (II) is: 2-(2,3,4-trihydroxyphenyl)-2-(2′,3′,4′-trihydroxyphenyl)propane, 2-(2,4-dihydroxyphenyl)-2-(2′,4′-dihydroxyphenyl)propane, 2-(4-hydroxyphenyl)-2-(4′-hydroxyphenyl)propane, bis(2,3,4-trihydroxyphenyl)methane or bis(2,4-dihydroxyphenyl)methane.

In addition, the ortho-naphthoquinone diazide sulfonic acid ester (B) may optionally include (4) other aromatic hydroxyl compounds. Specific examples of other aromatic hydroxyl compounds are: phenol, p-methoxyphenol, xylenol, hydroquinone, bisphenol A, naphthol, pyrocatechol, 1,2,3-pyrogallol monomethyl ether, 1,2,3-pyrogallol-1,3-dimethyl ether, 3,4,5-gallic acid or 3,4,5-gallic acid that is esterified or etherified partially.

Among those examples, the ortho-naphthoquinone diazide sulfonic acid ester (B) preferably includes the hydroxyaryl compounds and the (hydroxyphenyl) hydrocarbon compounds, and specific examples of which are: the ester of 1-[1-(4-hydroxyphenyl)isopropyl]-4-[1,1-bis(4-hydroxyphenyl)ethyl]benzene and naphthoquinone-1,2-diazido-5-sulfonate, the ester of 4,4′-ethylene-bis(2-methylphenol) and naphthoquinone-1,2-diazido-5-sulfonate, and the ester of 2,3,4,4′-tetrahydroxybenzophenone and naphthoquinone-1,2-diazido-5-sulfonate. The ortho-naphthoquinone diazide sulfonic acid ester (B) can be used alone or in combinations of two or more.

A compound including quinone diazide can be used as the ortho-naphthoquinone diazide sulfonic acid ester (B) in the positive photosensitive resin composition of the present invention, for example, the compound which is esterified completely or partially through the condensation reaction of the ortho-naphthoquinone diazide-4(or 5)-sulfonyl halides and the above-mentioned (1) to (4) hydroxyl compounds. The above-mentioned condensation reaction is generally performed in organic solvents such as dioxane, N-pyrrolidone, acetamide and the like, and preferably in the presence of alkaline condensing agents such as triethanolamine, alkali carbonate or alkali bicarbonate.

In preferred examples of the present invention, based on the total amount of the hydroxyl groups in the hydroxyl compound as 100 mole %, preferably more than 50 mole %, and more preferably more than 60 mole % of the hydroxyl compound and the ortho-naphthoquinone diazide-4(or 5)-sulfonyl halides both of which are condensed to the ester having an esterification degree of more than 50% and preferably more than 60%.

In a specific example of the present invention, based on the amount of the novolac resin (A) as 100 parts by weight, an amount of the ortho-naphthoquinone diazide sulfonic acid ester (B) of the present invention is generally 5 to 50 parts by weight, preferably 10 to 45 parts by weight, more preferably 15 to 40 parts by weight. When the ortho-naphthoquinone diazide sulfonic acid ester (B) includes the hydroxyaryl compounds or the (hydroxyphenyl) hydrocarbon compounds, the resulted positive photosensitive resin composition has better cross-sectional profile after being postbaked.

### Hydroxycompound (C)

The present hydroxycompound (C) may includes the above-mentioned hydroxyl compounds (1)-(4) used in the ortho-naphthoquinone diazide sulfonic acid ester (B), and the hydroxyl compounds (1)-(3) are preferred.

Among those hydroxyl compounds, the hydroxyl compound (2) is more preferably used in the hydroxycompound (C), and specific examples of which are: tris(4-hydroxyphenyl)methane, 1-[1-(4-hydroxyphenyl)isopropyl]-4-[1,1-bis(4-hydroxyphenyl)ethyl]benzene, bis(4-hydroxy-3,5-dimethylphenyl)phenyl methane, 2,4,6-trihydroxybenzophenone, 1,2,3-pyrogallol monomethyl ether and the like. The hydroxycompound (C) be used alone or in combinations of two or more.

Based on an amount of the novolac resin (A) as 100 parts by weight, the amount of the hydroxycompound (C) is generally 1 to 30 parts by weight, preferably 5 to 30 parts by weight, and more preferably 10 to 25 parts by weight. When the hydroxycompound (C) is not used in the positive photosensitive resin composition, the resulted positive photosensitive resin composition has the problem of bad cross-sectional profile after being postbaked. When the positive photosensitive resin composition has the aforementioned amounts of the hydroxycompound (C), the resulted positive photosensitive resin composition has the advantage of better cross-sectional profile after being postbaked.

### Solvent (D)

The solvent (D) used for the positive photosensitive resin composition of the present invention refers to organic solvents that easily dissolve with but do not react with other organic components.

In a specific embodiment of the present invention, the solvent (D) is (poly)alkylene glycol monoalkyl ethers such as ethylene glycol monomethyl ether, ethylene glycol monoethyl ether, diethylene glycol monoethyl ether, diethylene glycol mono-n-propyl ether, diethylene glycol mono-n-butyl ether, triethylene glycol monomethyl ether, triethylene glycol monoethyl ether, propylene glycol monomethyl ether, propylene glycol monoethyl ether, dipropylene glycol monomethyl ether, dipropylene glycol monoethyl ether, dipropylene glycol mono-n-propyl ether, dipropylene glycol mono-n-butyl ether, tripropylene glycol monomethyl ether, tripropylene glycol monoethyl ether and the like; (poly)alkylene glycol monoalkyl ether acetates such as ethylene glycol monomethyl ether acetate, ethylene glycol monoethyl ether acetate, propylene glycol monomethyl ether acetate, propylene glycol ether acetate and the like; other ethers such as diethylene glycol dimethyl ether, diethylene glycol methyl ether, diethylene glycol diethyl ether, tetrahydrofuran and the like; ketones such as methyl ethyl ketone, cyclohexanone, 2-heptanone, 3-heptanone and the like; lactic acid alkyl esters such as methyl 2-hydroxypropanoate methyl lactate, ethyl 2-hydroxypropanoate (also known as ethyl lactate) and the like; other esters such as methyl 2-hydroxy-2-methpropionate, ethyl 2-hydroxy-2-methpropionate, methyl 3-methoxypropionate, ethyl 3-methoxypropionate, methyl 3-ethoxypropionate, ethyl 3-ethoxypropionate, ethoxyethyl acetate, hydroxyethyl acetate, methyl 2-hydroxy-3-methylbutyrate, 3-methyl-3-methoxybutyl acetate, 3-methyl-3-methoxybutyl propionate, ethyl acetate, n-propyl acetate, isopropyl acetate, n-butyl acetate, isobutyl acetate, n-amyl acetate, isoamyl acetate, n-butyl propionate, ethyl butyrate, n-propyl butyrate, isopropyl butyrate, n-butyl butyrate, methyl pyruvate, ethyl pyruvate, n-propyl pyruvate, methyl acetoacetate, ethyl acetoacetate, ethyl 2-oxobutyrate and the like; aromatic hydrocarbons such as methylbenzene, dimethylbenzene and the like; carboxylic acid amides such as N-methylpyrrolidone, N,N-dimethylformamide, N,N-dimethylacetamide and the like. The aforementioned solvent (D) can be used alone or in combinations of two or more. Preferably, the solvent (D) is propylene glycol monoethyl ether, propylene glycol monomethyl ether acetate or ethyl lactate.

In a specific embodiment of the present invention, based on the amount of novolac resin (A) as 100 parts by weight, the amount of the aforementioned solvent (D) is generally 100 to 500 parts by weight; preferably 100 to 450 parts by weight; more preferably 100 to 400 parts by weight.

### Additive (E)

The positive photosensitive resin composition of the present invention may optionally include an additive (E), which may include but not limited to: an adhesiveness improver, a surface leveling agent, a diluent, a sensitizer and the like.

The aforementioned adhesiveness improver may include but not limited to a melamine compound and a silane compound, so as to improve the adhesiveness of the positive photosensitive resin composition adhered to the substrate. Specific examples of the aforementioned melamine are, for example, commercially available products Cymel-300, Cymel-303 (manufactured by CYTEC); MW-30MH, MW-30, MS-11, MS-001, MX-750 or MX-706 (manufactured by Sanwa Chemical). Specific examples of the aforementioned silane compound are, for example, vinyl trimethoxysilane, vinyl triethoxysilane, 3-(methyl)acryloxypropyl trimethoxysilane, vinyl tri(2-methoxyethoxy)silane, N-(2-aminoethyl)-3-aminopropyl methyl dimethoxy silane, N-(2-aminoethyl)-3-aminopropyl trimethoxysilane, 3-aminopropyl triethoxysilane, 3-glycidoxypropyl trimethoxysilane, 3-glycidoxypropyl dimethyl methoxysilane, 2-(3,4-epoxycyclohexyl)ethyl trimethoxysilane, 3-chloropropylmethyl dimethoxysilane, 3-chloropropyltrimethoxysilane, 3-mercapto propyl trimethoxy silane or bis-1,2-(trimethoxysilane)ethane.

In a specific embodiment of the present invention, based on the amount of novolac resin (A) as 100 parts by weight, the amount of the adherence additive in the aforementioned melamine compound is generally from 0 part by weight to 20 parts by weight, preferably from 0.5 parts by weight to 18 parts by weight, and more preferably from 1.0 parts by weight to 15 parts by weight; and the amount of the adherence additive in the aforementioned silane compound is generally from 0 parts by weight to 2 parts by weight, preferably from 0.001 parts by weight to 1 parts by weight, and more preferably from 0.005 parts by weight to 0.8 parts by weight.

The aforementioned surface leveling agent may include but not limited to a fluorine surfactant or a silane surfactant. Specific examples of the aforementioned fluorine surfactant are, for example, commercially available Flourate FC-430, FC-431 (manufactured by 3M) or F top EF122A, 122B, 122C, 126, BL20 (manufactured by Tochem product). Specific examples of the aforementioned silane surfactant are, for example, commercially available SF8427 or SH29PA (manufactured by Toray Dow Corning Silicone).

In a specific embodiment of the present invention, based on the amount of novolac resin (A) as 100 parts by weight, the amount of the aforementioned surfactant is generally from 0 parts by weight to 1.2 parts by weight, preferably from 0.025 parts by weight to 1.0 parts by weight, and more preferably from 0.050 parts by weight to 0.8 parts by weight.

A specific example of the aforementioned diluent is, for example, the commercially available products such as RE801 or RE802 (manufactured by Teikoku Printing Inks Mfg. Co., Ltd).

Specific examples of the aforementioned sensitizer are, for example, commercially available products such as TPPA-1000P, TPPA-100-2C, TPPA-1100-3C, TPPA-1100-4C, TPPA-1200-24X, TPPA-1200-26X, TPPA-1300-235T, TPPA-1600-3M6C or TPPA-MF (manufactured by Honshu Chemical Industry Co., Ltd.), and preferably TPPA-1600-3M6C or TPPA-MF. The aforementioned sensitizer can be alone or in combinations of two or more.

The aforementioned additives (E) can be used alone or in combinations of two or more. In a specific embodiment of the present invention, based on the amount of novolac resin (A) as 100 parts by weight, the amount of the aforementioned sensitizing agent is generally from 0 parts by weight to 20 parts by weight, preferably from 0.5 parts by weight to 18 parts by weight, and more preferably from 1.0 parts by weight to 5 parts by weight. Furthermore, the present invention can also use other additives if necessary, such as plasticizers and stabilizers.

Preparation Method of Positive Photosensitive Resin Composition

In general, the positive photosensitive resin composition of the present invention is prepared by mixing the aforementioned novolac resin (A), the ortho-naphthoquinone diazide sulfonic acid ester (B), the hydroxycompound (C) and the solvent (D) in a conventional mixer uniformly until all components are formed into form a solution state, optionally adding various additives (E) thereto if necessary, so as to obtain the positive photosensitive resin composition.

### Method for Forming Patterns

The aforementioned resulted positive photosensitive composition is sequentially subjected to a prebake step, an exposure step, a development step and a postbake step, so as to form a pattern on a substrate.

Particularly, the method for forming a pattern using the aforementioned positive photosensitive resin composition of the present invention is that by methods of spin coating, curtain coating or roll coating and the like, the aforementioned positive photosensitive resin composition is coated on the substrate, and the solvent is prebaked and removed after coating, so as to form a prebaked coating film. The conditions of prebake can be varied according to kings and mixture ratios of various components, and the prebaking is typically performed at a temperature of 70 to 110° C. for 1 to 15 minutes.

After being prebaking, the coated film is exposed under a desired light mask, and then the film is immersed in a developing solution at a temperature of 23±2° C. for 15 seconds to 5 minutes, so as to remove the undesired areas and form a given pattern. The exposure light is preferably UV light such as g-line, h-line, i-line and so on, which may be generated by a UV illumination device such as (super) high-pressure mercury lamp and metal halide lamp.

Specific examples of the developing solution used in the present invention are alkaline compounds such as sodium hydroxide, potassium hydroxide, sodium carbonate, sodium bicarbonate, potassium carbonate, potassium bicarbonate, sodium silicate, sodium methyl silicate, ammonia solution, ethylamine, diethylamine, dimethylethylanolamine, tetramethylammonium hydroxide, tetraethylammonium hydroxide, choline, pyrrole, piperidine or 1,8-diazabicylo-[5,4,0]-7-undecene and the like.

Preferably, the concentration of the developing solution is preferably 0.001 wt % to 10 wt %, more preferably 0.005 wt % to 5 wt %, and much more preferably 0.01 wt % to 1 wt %.

When the developing solution including the aforementioned alkaline compounds is used, the coated film can be washed by water after being developed, and then the coated film is dried through compressed air or compressed nitrogen gas. Subsequently, the film is postbaked through a heating apparatus such as a hot plate or an oven. The postbake step can be carried out at 100° C. to 250° C. for 1 to 60 minutes on the hot plate or for 5 to 90 minutes in the oven. After the aforementioned steps, a pattern is formed on the substrate.

The thickness of the resulted patterns is generally 5 μm to 25 μm, preferably 8 μm to 25 μm, and more preferably 10 μm to 25 μm. When the thickness of the resulted patterns is 5 μm to 25 μm, the patterns are beneficial to finely lay an electrically conducting layer, an insulating layer or a protection film.

### TFT Array Substrate

The TFT array substrate of the present invention is manufactured through the aforementioned method. In brief, the positive photosensitive resin composition of the present invention is coated on a glass substrate or plastic substrate by using coating methods such as spin coating, curtain coating or roll coating, to form a positive photoresist layer. Subsequently, after the positive photoresist layer is treated through the steps of prebake, exposure development and postbake, the resulted photosensitive resin pattern is etched and stripped. After the aforementioned steps are repeated, a TFT array substrate including multiple TFTs or electrodes is obtained.

Reference is made to FIG. 1, which illustrates a partially cross-sectional view of a TFT array substrate used for a LCD device according to an embodiment of the present invention. Firstly, a gate electrode 102a and a storage capacitor Cs electrode 102b are configured on an aluminium thin film of a glass substrate 101. Moreover, a silicon oxide (SiOₓ) film 103 or silicon nitride (SiNₓ) film 104 is covered with the gate electrode 102a to form a dielectric film, and then an amorphous silicon (a-Si) layer 105 is formed on the dielectric film as a semiconductor active layer. Afterwards, in order to reduce the interface impedance, an amorphous silicon layer 106 doped with nitrogen impurities may be disposed on the amorphous silicon layer 105. Then, a metal such as aluminium is formed to a drain electrode 107a and a source electrode 107b, in which the drain electrode 107a is connected to a data signal line (unshown), and the source electrode 107b is connected to a pixel electrode (or called as a subpixel electrode) 109. Thereafter, a silicon nitride film is disposed as a protective film 108 for protecting the underlying semiconductor active layer such as the amorphous silicon layer 105, the drain electrode 107a, the source electrode 107b and the like.

### LCD Device

The LCD device of the present invention at least includes the aforementioned TFT array substrate, as well as other components if necessary.

The specific examples of the basic structure of the aforementioned LCD unit are as follows. (1) The TFT array substrate (driving substrate) is arranged by driving devices such as TFT and the pixel electrode. A color filter substrate includes a color filter and a counter electrode (or called as a conductive layer). The TFT array substrate (driving substrate) and the color filter substrate are opposed to each other where spacers are interposed therebetween. The space between the two substrates is filled with liquid crystal material and then sealed to form the LCD device. Alternatively, (2) an integrated TFT array substrate is provided which includes a color filter directly formed on the aforementioned TFT array substrate of the present invention. The integrated TFT array substrate and a counter substrate with a counter electrode (conductive layer) are opposed to each other where spacers are interposed therebetween. The space between the two substrates is filled with liquid crystal material and then sealed to form the LCD device. The aforementioned liquid crystal material can be any prior LC compound or composition without any limitation.

The specific example of the aforementioned conductive layer is an indium-tin oxide (ITO) film; metal films such as aluminum, zinc, copper, iron, nickel, chromium and molybdenum and the like; or metal oxide films such as silicon dioxide and the like. Preferably, the conductive layer is a transparent film layer, and more an ITO film.

Specific examples of the substrates used for the TFT array substrate, the color filter substrate and the counter substrate of the present invention are conventional glasses such as Na—Ca glass, low-expansion glass, alkali-free glass or quartz glass. In addition, a substrate constituted by plastic films also can be used.

Thereinafter, various applications of the present invention will be described in more details referring to several exemplary embodiments below, while not intended to be limiting. Thus, one skilled in the art can easily ascertain the essential characteristics of the present invention and, without departing from the spirit and scope thereof, can make various changes and modifications of the invention to adapt it to various usages and conditions.

### BRIEF DESCRIPTION OF THE DRAWINGS

In order to make the above aspects, features, advantages and embodiments of the present invention more apparent, the accompanying drawings are illustrated as follows:

FIG. 1 illustrates a partially cross-sectional view of a TFT array substrate used for a LCD device according to an embodiment of the present invention.

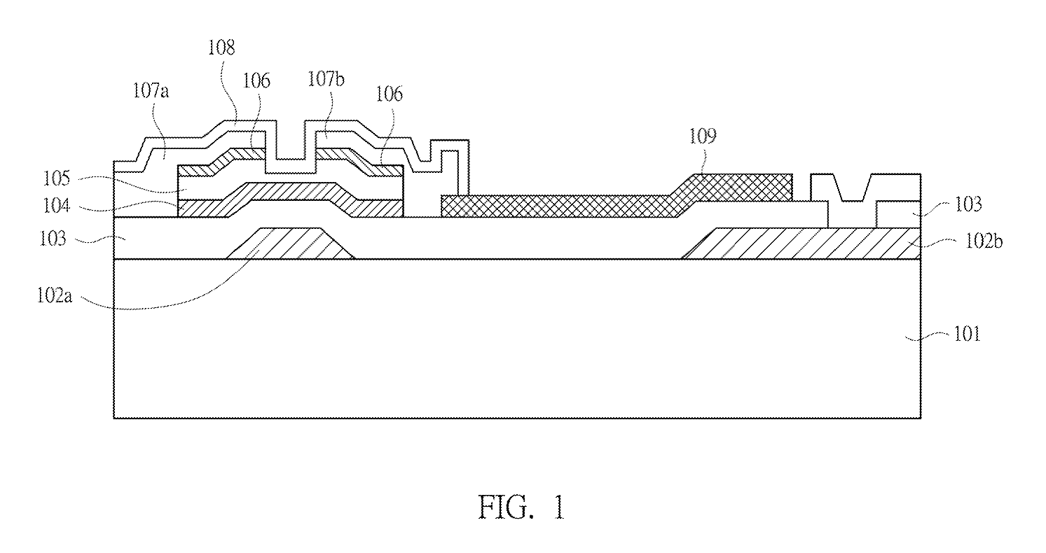

FIG. 2 illustrates several cross-sectional views for evaluating cross-sectional profiles of the protection films with patterns of Examples 1 to 10 and Comparative Examples 1 to 7

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

### Preparation of Novolac Resin (A)

The hydroxy-type novolac resin (A-1) was prepared by Synthesis Examples A-1-1 to A-3-3 according to TABLE 1.

### Synthesis Example A-1-1

A 1000 mL four-necked conical flask equipped with a nitrogen inlet, a stirrer, a heater, a condenser and a thermometer was purged with nitrogen, and the following components were charged to the flask. The aforementioned components comprising 0.70 moles of m-cresol, 0.30 moles of p-cresol, 0.5 moles of 3,4-dihydroxybenzaldehyde and 0.020 moles of oxalic acid were stirred slowly and heated to 100° C., so as to carry out polycondensation for 6 hours. Next, the reaction was heated again to 180° C. and then dried under a decreased pressure at 10 mmHg for evaporating the solvent, thereby obtaining a hydroxy-type novolac resin (A-1-1).

### Synthesis Examples A-1-2 to A-3-3

Synthesis Examples A-1-2 to A-3-3 were practiced with the same method as in Synthesis Example A-1-1 by using different kinds and different amounts of the components of the hydroxy-type novolac resin (A-1). The formulations of Synthesis Examples A-1-2 to A-3-3 were also listed in TABLE 1 rather than focusing or mentioning them in detail.

### Preparation of Positive Photosensitive Resin Composition

The following examples are directed to the preparation of the positive photosensitive resin composition of Examples 1 to 10 and Comparative Examples 1 to 7 according to TABLES 2 and 3.

### Example 1

70 parts by weight of the hydroxy-type novolac resin (A-1-1) of Synthesis Example A-1-1, 30 parts by weight of the hydroxy-type novolac resin (A-2-1) of Synthesis Example A-2-1, 30 parts by weight of the ester of 1-[1-(4-hydroxyphenyl)isopropyl]-4-[1,1-bis(4-hydroxyphenyl)ethyl]benzene and naphthoquinone-1,2-diazido-5-sulfonate (B-1) (85% of average esterification degree) and 10 parts by weight of tris(4-hydroxyphenyl)methane (C-1) were added into 300 parts by weight of propylene glycol monomethyl ether acetate (PGMEA) of the solvent (D-1), and the aforementioned mixture was stirred and dissolved in the solvent by a shaking mixer, so as to form a positive photosensitive resin composition of Example 1 of the present invention. And then, the properties of the positive photosensitive resin composition were determined by using the following evaluation methods and resulted in TABLE 2. The detection methods of the film thickness and the cross-sectional profile of the postbaked patterns were described as follows.

### Examples 2 to 10

Examples 2 to 10 were practiced with the same method as in Example 1 by using different kinds and different amounts of the components of the positive photosensitive resin composition. The formulations of Examples 2 to 10 were also listed in TABLE 2 rather than focusing or mentioning them in detail.

### Comparative Examples 1 to 7

Comparative Examples 1 to 7 were practiced with the same method as in Example 1 by various kinds or usage of the components. The formulation and the evaluation results were also listed in TABLE 3.

Evaluation Methods

1. Film Thickness of Postbaked Patterns

The positive photosensitive resin compositions of Examples 1 to 10 and Comparative Examples 1 to 7 were spin-coated on a glass substrate, and then prebaked at 100° C. for 120 seconds, thereby obtaining a prebaked and coated film with a thickness of about 10 μm. And then, the prebaked and coated film was placed under a given mask (manufactured by Filcon Co., Japan), and irradiated by ultraviolet light of 200 mJ/cm² (exposure machine Model No. AG500-4N; manufactured by M&R Nano Technology). Next, the film was developed in 2.38% of TMAH solution at 23° C. for 3 minutes, and then the exposed portion of the film on the substrate was removed. Subsequently, the remained pattern of the films was washed by pure water and obtained. The film was postbaked at 120° C. for 2 minutes, so as to obtain a glass substrate containing patterns as a protection film. The film thickness of the protection film was measured by an optical film thickness meter (Model No. MFS-630-F; manufactured by Hong-Ming Technology Co., Ltd.).

2. Cross-Sectional Profile of Postbaked Patterns

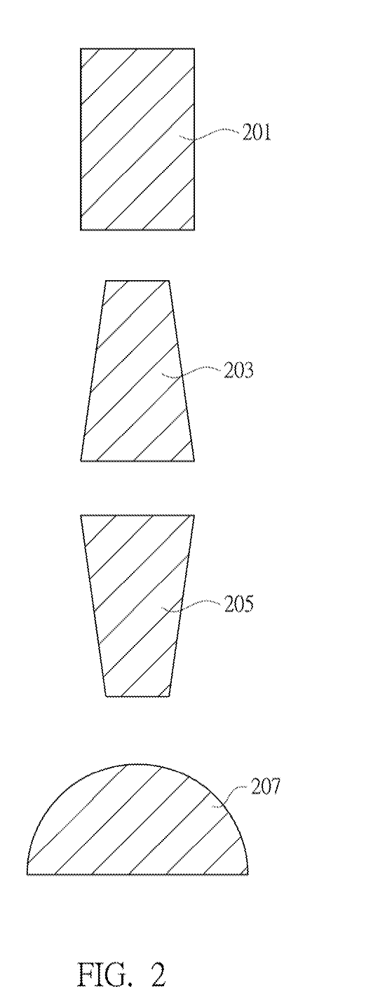

The cross-sectional profiles of the protection films with patterns of Examples 1 to 10 and Comparative Examples 1 to 7 were photographed by scanning electron microscopy (SEM) and evaluated according to the following criterion and several cross-sectional views of FIG. 2.

⊚: Vertical Cross-Section of Vertical Sidewalls 201

◯: Vertical Cross-Section of Cone 203

X: Vertical Cross-Section of Upside-Down Cone 205

The evaluation results of the film thickness and the cross-sectional profile of the postbaked patterns of the positive photosensitive resin composition resulted from the aforementioned Examples and Comparative Examples were shown in TABLES 2 and 3.

As shown in the results in TABLES 2 and 3, when the positive photosensitive resin composition included the specific ratio of the hydroxy-type novolac resin (A-1) and the xylenol-type novolac resin (A-2), the resulted pattern had advantages such as high film thickness and well cross-sectional profile after being postbaked. Moreover, the ortho-naphthoquinone diazide sulfonic acid ester (B) that had the hydroxyaryl compounds or the (hydroxyphenyl) hydrocarbon compound was used in the positive photosensitive resin composition, better cross-sectional profile of the resulted pattern could be achieved advantageously when such positive photosensitive resin composition further included the hydroxyaryl compound as the hydroxycompound (C), thereby achieving the purpose of the present invention actually.

It should be supplemented that, although specific compounds, components, reaction conditions, processes, evaluation methods or specific equipments are described as examples of the present invention, for illustrating the positive photosensitive resin composition of the present invention and the method for forming patterns by using the same. However, as is understood by a person skilled in the art instead of limiting to the aforementioned examples, the positive photosensitive resin composition of the present invention and the method for forming patterns by using the same also can be manufactured by using other compounds, components, reaction conditions, processes, evaluation methods and equipments without departing from the spirit and scope of the present invention.

Although the present invention has been disclosed with reference to the embodiments above, these embodiments are not intended to limit the present invention. In view of the foregoing, it is intended to cover various modifications and similar arrangements included within the spirit and scope of the appended claims. Therefore, the scope of the present invention should be accorded the broadest interpretation so as to encompass all such modifications and similar structure.

TABLE 1

| | Composition (Moles) | | | | | | | |
|---|---|---|---|---|---|---|---|---|
| | | | | | | | Aldehydes | |
| | Aromatic Hydroxyl Compound | | | | | | 3,4- | o- |
| Synthesis | | | | 3,5- | 3,4- | 2,5- | dihydroxy | hydroxy |
| Examples | o-cresol | m-cresol | p-cresol | xylenol | xylenol | xylenol | benzaldehyde | benzaldehyde |
| A-1-1 | | 0.7 | 0.3 | | | | 0.5 | |
| A-1-2 | 0.1 | 0.4 | 0.5 | | | | | 0.6 |
| A-1-3 | | 0.4 | 0.6 | | | | 0.25 | |
| A-2-1 | | 0.4 | 0.5 | | 0.1 | | | |
| A-2-2 | | 0.3 | 0.55 | 0.05 | | | | |
| A-2-3 | | 0.5 | 0.4 | | 0.05 | 0.05 | | |
| A-3-1 | | 0.7 | 0.3 | | | | | |
| A-3-2 | | 0.5 | 0.5 | | | | | |
| A-3-3 | 0.05 | 0.65 | 0.3 | | | | | |

| | Composition (Moles) | | | | | |
|---|---|---|---|---|---|---|
| | Aldehydes | | | | | |
| | 2,3,4- | | | Catalyst | Reaction | |
| Synthesis | trihydroxy | | | oxalic | Temperature | Condensation |
| Examples | benzaldehyde | formaldehyde | benzaldehyde | acid | (° C.) | Time (Hour) |
| A-1-1 | | | | 0.02 | 100 | 6 |
| A-1-2 | | | | 0.015 | 95 | 6 |
| A-1-3 | 0.4 | | | 0.02 | 100 | 6 |
| A-2-1 | | 0.65 | | 0.2 | 100 | 6 |
| A-2-2 | | 0.7 | | 0.02 | 100 | 6 |
| A-2-3 | | | 0.65 | 0.02 | 100 | 6 |
| A-3-1 | | 0.7 | | 0.015 | 100 | 6 |
| A-3-2 | | | 0.6 | 0.02 | 100 | 6 |
| A-3-3 | | 0.65 | | 0.02 | 100 | 6 |

TABLE 2

| | | | Examples | | | | | | | | | |
|---|---|---|---|---|---|---|---|---|---|---|---|---|
| Composition | | | 1 | 2 | 3 | 4 | 5 | 6 | 7 | 8 | 9 | 10 |
| Novolac Resin (A) | A-1 | A-1-1 | 70 | | | 80 | | | | 40 | | |
| (parts by weight) | | A-1-2 | | 80 | | | 50 | | 70 | | 40 | |
| | | A-1-3 | | | 95 | | | 60 | | | | 60 |
| | A-2 | A-2-1 | 30 | | | | | | | | 60 | |
| | | A-2-2 | | 20 | | 5 | | 40 | | 40 | | |
| | | A-2-3 | | | 5 | | 45 | | 20 | | | 40 |
| | A-3 | A-3-1 | | | | 15 | | | | 20 | | |
| | | A-3-2 | | | | | 5 | | | | | |
| | | A-3-3 | | | | | | | 10 | | | |

| o-Naphthoquinone Diazide | B-1 | 30 | | 20 | | | 15 | 25 | 20 | | |
|---|---|---|---|---|---|---|---|---|---|---|---|
| Sulfonic Acid Ester (B) | B-2 | | 25 | | 10 | 5 | 5 | | | 40 | |
| (parts by weight) | B-3 | | | 5 | | | | | | | 50 |
| Hydroxycompound (C) | C-1 | 10 | | | | | 5 | | | | |
| (parts by weight) | C-2 | | 20 | | | | | 15 | 5 | | |
| | C-3 | | | 30 | | | 10 | | | 5 | |
| | C-4 | | | | 5 | | | 15 | | | 5 |
| | C-5 | | | | | 1 | | | | | |
| Solvent (D) | D-1 | 300 | 250 | 150 | | 100 | | 300 | | 200 | 150 |
| (parts by weight) | D-2 | | | | 200 | | 400 | 200 | 300 | | |
| | D-3 | | | 50 | | | | | | | 100 |
| Additive (E) | E-1 | | 1 | | 0.3 | | | | | | |
| | E-2 | | | | | | 2 | | | | |
| (A-1)/[(A-1) + (A-2)](wt %) | | 70 | 80 | 95 | 94.1 | 52.6 | 60 | 77.8 | 50 | 40 | 60 |
| Evaluation Items | Flim Thickness (μm) | 11 | 14 | 19 | 15 | 25 | 7 | 5 | 8 | 15 | 12 |
| | of Postbaked | | | | | | | | | | |
| | Patterns | | | | | | | | | | |
| | Cross-Sectional | ⊚ | ⊚ | ⊚ | ◯ | ◯ | ⊚ | ⊚ | ◯ | ◯ | ◯ |
| | Profile of Postbaked | | | | | | | | | | |
| | Patterns | | | | | | | | | | |

TABLE 3

| | | | Comparative Examples | | | | | | |
|---|---|---|---|---|---|---|---|---|---|
| Composition | | | 1 | 2 | 3 | 4 | 5 | 6 | 7 |
| Novolac Resin (A) | A-1 | A-1-1 | | | | | | | |
| (parts by weight) | | A-1-2 | | 60 | | | | 100 | |
| | | A-1-3 | | | 60 | | | | |
| | A-2 | A-2-1 | 70 | | | | | | |
| | | A-2-2 | | | | | 100 | | |
| | | A-2-3 | | | 40 | | | | |
| | A-3 | A-3-1 | 30 | | | 100 | | | |
| | | A-3-2 | | 40 | | | | | 100 |
| | | A-3-3 | | | | | | | |

| o-Naphthoquinone Diazide | B-1 | 25 | | 20 | 15 | 20 | 20 | |
|---|---|---|---|---|---|---|---|---|
| Sulfonic Acid Ester (B) | B-2 | | 20 | | | | | 20 |
| (parts by weight) | B-3 | | | 5 | | | | |
| Hydroxycompound (C) | C-1 | | | | | | | |
| (parts by weight) | C-2 | 10 | | | | | | |
| | C-3 | | 10 | | | | | |
| | C-4 | | | | 10 | | | |
| | C-5 | | | | | | | |
| Solvent (D) | D-1 | 250 | | 250 | 300 | | 350 | 250 |
| (parts by weight) | D-2 | | 300 | | | 300 | | |
| | D-3 | | | | | | | |
| Additive (E) | E-1 | | | | | | | |
| | E-2 | | | | | | | |
| (A-1)/[(A-1) + (A-2)] (wt. %) | | 0 | 100 | 60 | — | 0 | 100 | — |
| Evaluation Items | Film Thickness (μm) | 4 | 3 | 10 | 3 | 2 | 1 | 2 |
| | of Postbaked | | | | | | | |
| | Patterns | | | | | | | |
| | Cross-Sectional | X | X | X | X | X | X | X |
| | Profile of Postbaked | | | | | | | |
| | Patterns | | | | | | | |

B-1 the ester of 1-[1-(4-hydroxyphenyl) isopropyl]-4-[1,1-bis(4-hydroxyphenyl) ethyl] benzene and naphthoquinone-1,2-diazido-5-sulfonate
B-2 the ester of 4,4′-ethylene-bis(2-methylphenol) and naphthoquinone-1,2-diazido-5-sulfonate
B-3 the ester of 2,3,4,4′-tetrahydroxybenzophenone and naphthoquinone-1,2-diazido-5-sulfonate
C-1 tris(4-hydroxyphenyl) methane
C-2 1-[1-(4-hydroxyphenyl) isopropyl]-4-[1,1-bis(4-hydroxyphenyl) ethyl] benzene
C-3 bis(4-hydroxy-3,5-dimethylphenyl)phenyl methane
C-4 2,4,6-trihydroxybenzophenone
C-5 1,2,3-pyrogallol monomethyl ether
D-1 propylene glycol monomethyl ether acetate (PGMEA)
D-2 ethyl lactate (EL)
D-3 propylene glycol monoethyl ether (PGEE)
E-1 surfactant; commercial name SF8427 (manufactured by Toray Dow Corning Silicone)
E-2 adhesiveness improver; commercial name Cymel-303 (manufactured by CYTEC)

What is claimed is:

1. A positive photosensitive resin composition, comprising:
novolac resin (A), wherein the novolac resin (A) comprises hydroxy-type novolac resin (A-1) and xylenol-type novolac resin (A-2), the hydroxy-type novolac resin (A-1) is formed by condensing hydroxyl benzaldehyde compound with aromatic hydroxyl compound, and the xylenol-type novolac resin (A-2) is synthesized by condensing aldehyde compound with xylenol compound;
ortho-naphthoquinone diazide sulfonic acid ester (B);
a hydroxycompound (C); and
a solvent (D).

2. The positive photosensitive resin composition of claim 1, wherein the ortho-naphthoquinone diazide sulfonic acid ester (B) comprises hydroxybenzophenone and/or hydroxyaryl compound and/or (hydroxyphenyl) hydrocarbon compound.

3. The positive photosensitive resin composition of claim 1, wherein the hydroxycompound (C) comprises hydroxybenzophenone and/or hydroxyaryl compound and/or (hydroxyphenyl) hydrocarbon compound.

4. The positive photosensitive resin composition of claim 1, wherein based on an amount of the novolac resin (A) as 100 parts by weight, an amount of the hydroxy-type novolac resin (A-1) is 50 to 95 parts by weight, an amount of the xylenol-type novolac resin (A-2) is 5 to 50 parts by weight, an amount of the ortho-naphthoquinone diazide sulfonic acid ester (B) of the present invention is 5 to 50 parts by weight, an amount of the hydroxycompound (C) is 1 to 30 parts by weight, and an amount of the aforementioned solvent (D) is 100 to 500 parts by weight.

5. The positive photosensitive resin composition of claim 4, wherein based on a total amount of the hydroxy-type novolac resin (A-1) and the xylenol-type novolac resin (A-2) as 100 percentage by weight, the amount of the hydroxy-type novolac resin (A-1) is 50 to 95 percentage by weight, and the amount of the xylenol-type novolac resin (A-2) is 5 to 50 percentage by weight.

6. A method for forming patterns, wherein a positive photosensitive resin composition is sequentially subjected to a prebake step, an exposure step, a development step and a postbake step, so as to form a pattern on a substrate, wherein positive photosensitive resin composition comprises:
novolac resin (A), wherein the novolac resin (A) comprises hydroxy-type novolac resin (A-1) and xylenol-type novolac resin (A-2), the hydroxy-type novolac resin (A-1) is formed by condensing hydroxyl benzaldehyde compound with aromatic hydroxyl compound, and the xylenol-type novolac resin (A-2) is synthesized by condensing aldehyde compound with xylenol compound;
ortho-naphthoquinone diazide sulfonic acid ester (B);
a hydroxycompound (C); and
a solvent (D).

7. The method for forming patterns of claim 6, wherein the ortho-naphthoquinone diazide sulfonic acid ester (B) comprises hydroxybenzophenone and/or hydroxyaryl compound and/or (hydroxyphenyl) hydrocarbon compound.

8. The method for forming patterns of claim 6, wherein the hydroxycompound (C) comprises hydroxybenzophenone and/or hydroxyaryl compound and/or (hydroxyphenyl) hydrocarbon compound.

9. The method for forming patterns of claim 6, wherein based on an amount of the novolac resin (A) as 100 parts by weight, an amount of the hydroxy-type novolac resin (A-1) is 50 to 95 parts by weight, an amount of the xylenol-type novolac resin (A-2) is 5 to 50 parts by weight, an amount of the ortho-naphthoquinone diazide sulfonic acid ester (B) of the present invention is 5 to 50 parts by weight, an amount of the hydroxycompound (C) is 1 to 30 parts by weight, and an amount of the aforementioned solvent (D) is 100 to 500 parts by weight.

10. The method for forming patterns of claim 9, wherein based on a total amount of the hydroxy-type novolac resin (A-1) and the xylenol-type novolac resin (A-2) as 100 percentage by weight, the amount of the hydroxy-type novolac resin (A-1) is 50 to 95 percentage by weight, and the amount of the xylenol-type novolac resin (A-2) is 5 to 50 percentage by weight.

11. The method for forming patterns of claim 6, wherein a film thickness of the pattern is 5 μm to 25 μm.

12. A thin film transistor array substrate comprising the pattern of claim 6.

13. A liquid crystal display device comprising the thin film transistor array substrate of claim 12.
